(19) United States
(12) Patent Application Publication
(10) Pub. No.: US 2018/0094353 A1
(43) Pub. Date: Apr. 5, 2018

(54) GAS INJECTOR DEVICE USED FOR SEMICONDUCTOR EQUIPMENT

(71) Applicant: HERMES-EPITEK CORPORATION, Taipei City (TW)

(72) Inventors: Tsan-Hua Huang, Tainan City (TW); Po-Jung Lin, Hsinchu (TW)

(21) Appl. No.: 15/712,032

(22) Filed: Sep. 21, 2017

(30) Foreign Application Priority Data
Sep. 30, 2016 (TW) 105131760

(51) Int. Cl. C23C 16/455; B05B 15/02

(52) U.S. Cl. CPC C23C 16/45563; B05B 15/02

(57) ABSTRACT

A gas injector includes a base plate, a center sleeve cover, an intake body, an inner cover and an outer cover. The base plate includes a plurality of channels. The center sleeve cover is operatively coupled with the base plate to form a first cavity, a wall of the center sleeve cover having a plurality of first communicating openings correspondingly connected to first channels. The intake body includes a top portion, an inner wall and an outer wall. The inner cover is disposed between the center sleeve cover and the inner wall to result in a second cavity, the inner cover having a plurality of second communicating openings correspondingly connected to second channels. The outer cover is disposed between the inner wall and the outer wall to result in a third cavity, the outer cover having a plurality of third communicating openings correspondingly connected to third channels.

### CROSS-REFERENCE TO RELATED APPLICATIONS

This application claims priority of Taiwan Application No. 105131760, filed on Sep. 30, 2016, the entire contents of which are hereby incorporated by reference.

### BACKGROUND OF THE INVENTION

### 1. Field of the Invention

The present invention generally relates to a gas injector, and more particularly to a gas injector adaptable to semiconductor equipment.

### 2. Description of Related Art

Chemical vapor deposition (CVD) equipment has been widely used in a semiconductor process. The CVD equipment commonly adopts gas injectors that are vertically stacked and separated for transferring gasses to a chamber.

FIG. 1 shows a cross-sectional view of a gas injector 100 of conventional CVD equipment. The gas injector 100 includes a first pipe 111, a second pipe 112 and a third pipe 113, which are vertically separated from each other. As output ends of the first pipe 111, the second pipe 112 and the third pipe 113 are vertically stacked, output gases are unidirectionally and vertically distributed. The output gasses are apt to mix at the output ends. Moreover, flow velocities of the output gasses cannot be adjusted instantly.

A need has thus arisen to propose a novel gas injector adaptable to semiconductor equipment capable of distributing gasses horizontally, preventing gasses from mixing at the output ends and adjusting gas flow velocities.

### SUMMARY OF THE INVENTION

In view of the foregoing, it is an object of the embodiment of the present invention to provide an automatic gas injector adaptable to semiconductor equipment for distributing gasses horizontally, preventing gasses from mixing at gas nozzles and effectively adjusting gas flow velocities instantly.

According to one embodiment, a gas injector includes a base plate, a center sleeve cover, an intake body, an inner cover and an outer cover. The base plate includes a central zone and a plurality of channels, the channels surrounding the central zone and being disposed on the base plate in sequence, the channels including first channels, second channels and third channels. The center sleeve cover is disposed in the central zone and operatively coupled with the base plate to form a first cavity, a wall of the center sleeve cover joining the channels and having a plurality of first communicating openings correspondingly connected to the first channels. The intake body includes a top portion, an inner wall and an outer wall, top surfaces of the inner wall and the outer wall being connected to the top portion, and bottom surfaces of the inner wall and the outer wall being disposed on the channels. The inner cover is disposed above the channels and disposed between the center sleeve cover and the inner wall to result in a second cavity, the inner cover having a plurality of second communicating openings correspondingly connected to the second channels. The outer cover is disposed above the channels and disposed between the inner wall and the outer wall to result in a third cavity, the outer cover having a plurality of third communicating openings correspondingly connected to the third channels.

### BRIEF DESCRIPTION OF THE DRAWINGS

FIG. 1 shows a cross-sectional view of a gas injector of conventional CVD equipment;

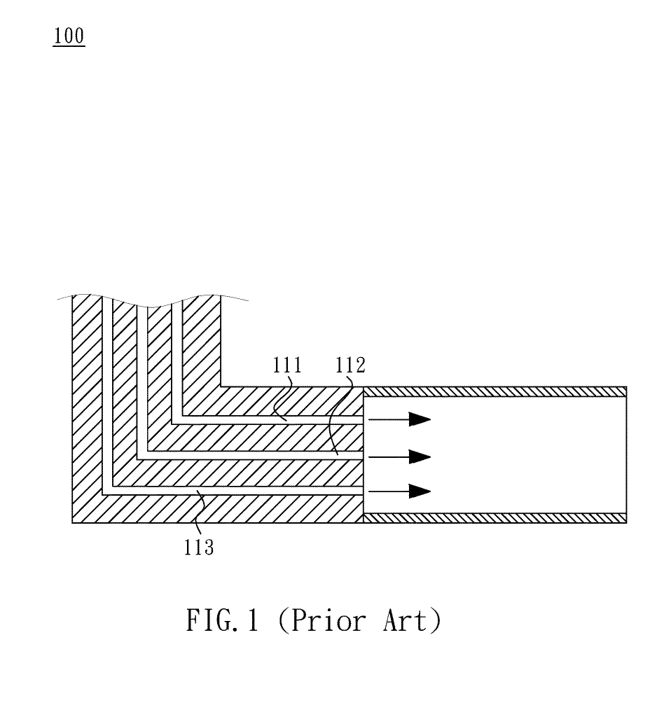

FIG. 2A shows an exploded view of a gas injector adaptable to semiconductor equipment according to one embodiment of the present invention;

FIG. 2B shows a partial cross-sectional view of the gas injector of FIG. 2A;

FIG. 2C shows a perspective view of the center sleeve cover and the base plate of FIG. 2A in combination;

FIG. 2D shows a perspective view of the inner cover, the outer cover and the base plate of FIG. 2A in combination; and

FIG. 2E shows a partial cross-sectional view of a gas injector adaptable to semiconductor equipment according to another embodiment of the present invention.

### DETAILED DESCRIPTION OF THE INVENTION

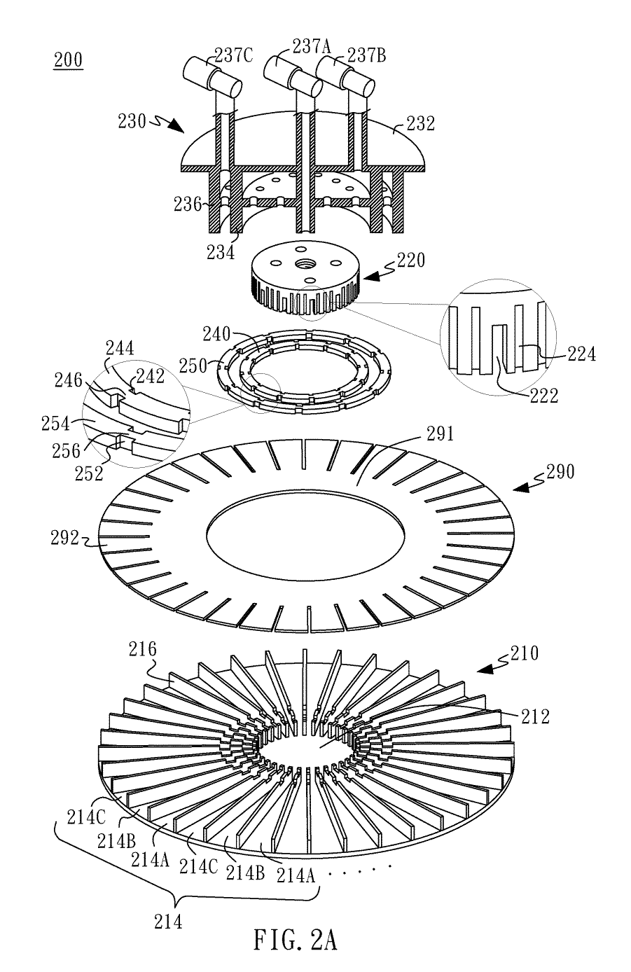

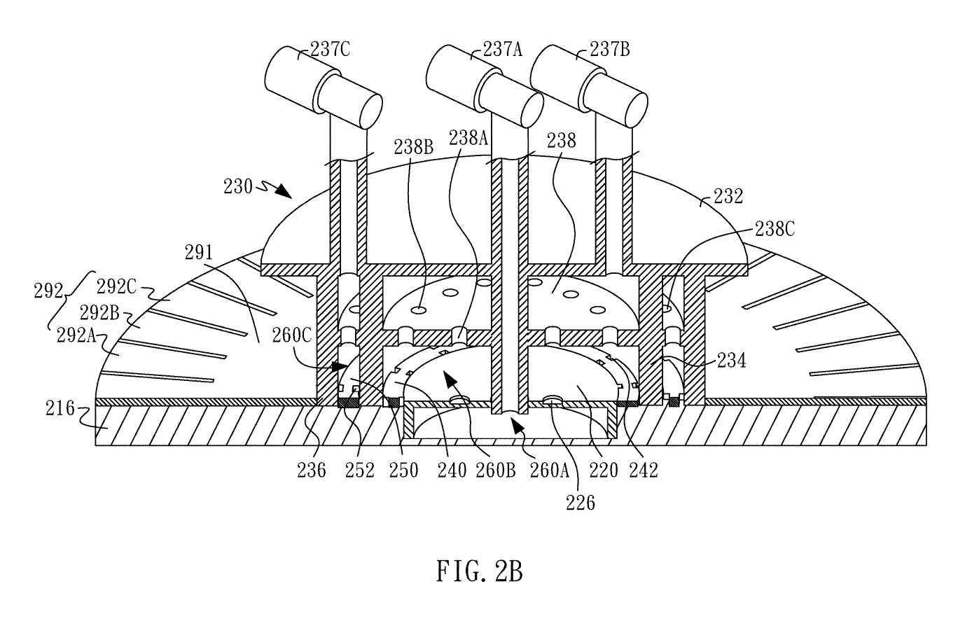

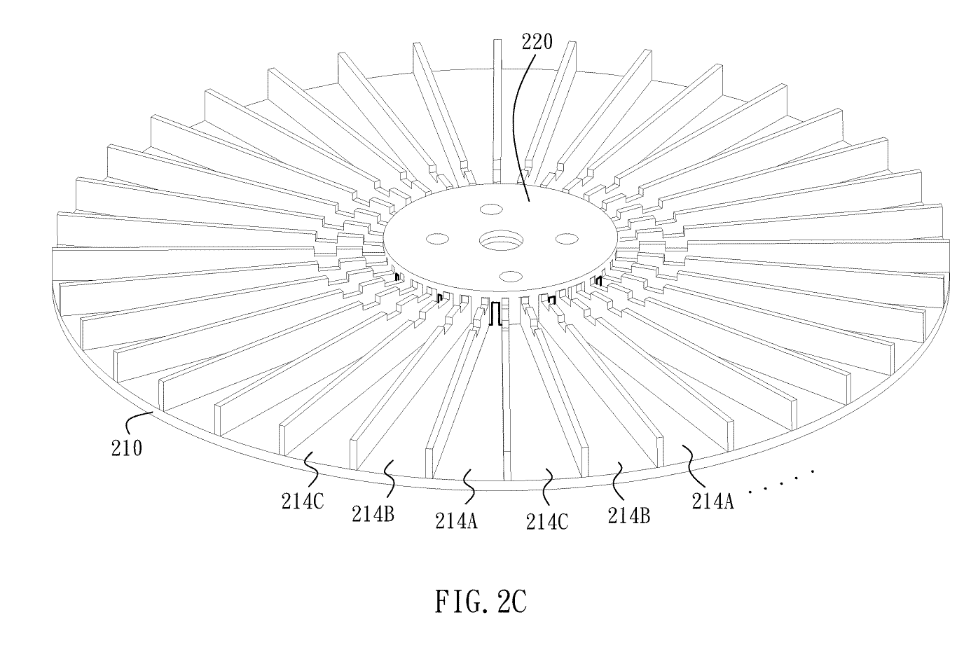

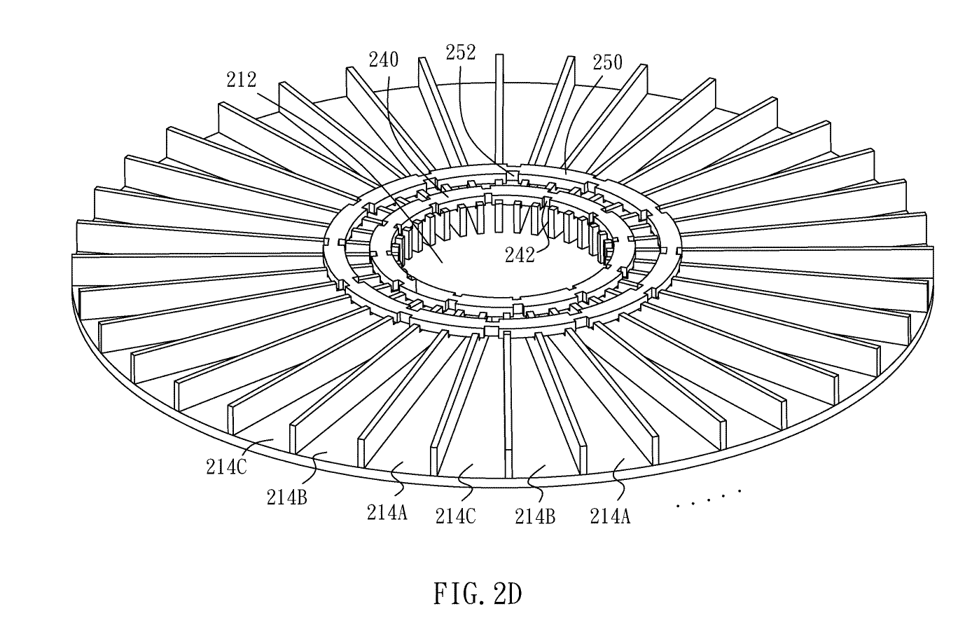

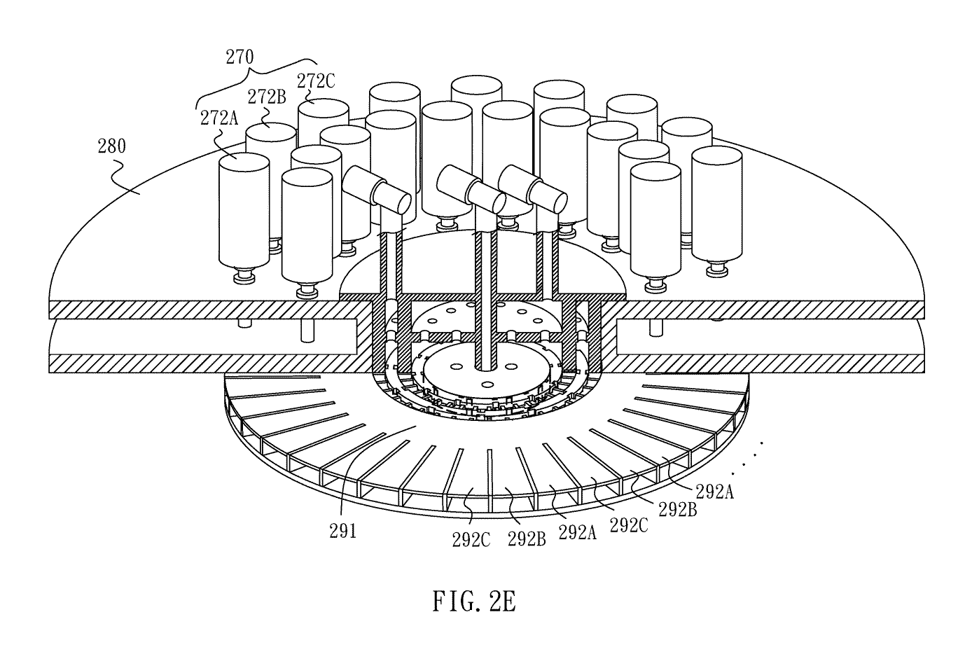

FIG. 2A shows an exploded view of a gas injector 200 adaptable to semiconductor equipment according to one embodiment of the present invention, and FIG. 2B shows a partial cross-sectional view of the gas injector 200 of FIG. 2A. The gas injector 200 of the embodiment may include a base plate 210, a center sleeve cover 220, an intake body 230, an inner cover 240 and an outer cover 250. The base plate 210 has a central zone 212 and a plurality of channels 214. The channels 214, surrounding the central zone 212, are disposed on the base plate 210 in sequence. The channels 214 may include first channels 214A, second channels 214B and third channels 214C. The center sleeve cover 220 is disposed in the central zone 212, and is operatively coupled with the base plate 210 to form a first cavity 260A. Specifically, a wall of the center sleeve cover 220 joins inner ends of the channels 214, and has a plurality of first communicating openings 222 correspondingly connected to the first channels 214A. The intake body 230 may include a top portion 232, an inner wall 234 and an outer wall 236. Specifically, top surfaces of the inner wall 234 and the outer wall 236 are connected to the top portion 232, and bottom surfaces of the inner wall 234 and the outer wall 236 are disposed on the channels 214. The inner cover 240 is disposed above the channels 214, and is disposed between the center sleeve cover 220 and the inner wall 234 to result in a second cavity 260B. The inner cover 240 may have a plurality of second communicating openings 242 correspondingly connected to the second channels 214B. The outer cover 215 is disposed above the channels 214, and is disposed between the inner wall 234 and the outer wall 236 to result in a third cavity 260C. The outer cover 250 may have a plurality of third communicating openings 252 correspondingly connected to the third channels 214C.

In the embodiment, the intake body 230 may further include a first pipe 237A, a second pipe 237B and a third pipe 237C. The first pipe 237A passes through the top portion 232 of the intake body 230, and connects to the center sleeve cover 220 for providing first gas to the first cavity 260A. The second pipe 237B is disposed on the top portion 232 of the intake body 230, and is connected to the second cavity 260B for providing second gas to the second cavity 260B. The third pipe 237C is disposed on the top portion 232 of the intake body 230, and is connected to the third cavity 260C for providing third gas to the third cavity 260C.

In the embodiment, as shown in FIG. 2B, the intake body 230 may further include an auxiliary plate 238 (embedded between the inner wall 234 and the outer wall 236) that is horizontally arranged and is parallel with the top portion 232. The auxiliary plate 238 may have a plurality of first holes 238A disposed above the center sleeve cover 220. A fastener may pass through the first hole 238A, and then connect to a slot 226 of the center sleeve cover 220, thereby fastening the intake body 230 to the center sleeve cover 220. Alternatively, the slot 226 may be replaced with an opening via which the fastener can screw or joggle joint to the center sleeve cover 220. Moreover, the auxiliary plate 238 may have a plurality of second holes 238B and third holes 238C correspondingly connected to the second communicating openings 242 and the third communicating openings 252 respectively, such that the second gas and the third gas can enter the second channels 214B and the third channels 214C via the second communicating openings 242 and the third communicating openings 252, respectively.

The base plate 210 may include a plurality of separating plates 216 configured for separating the channels 214, such that gases in the first channels 214A, the second channels 214B and the third channels 214C will not mix before injecting.

In one embodiment, there are N (a positive integer) first channels 214A, N second channels 214B and N third channels 214C on the base plate 210. The sequence of the first channels 214A, the second channels 214B and the third channels 214C may be arranged according to specific requirements. As exemplified in FIG. 2A, the first channel 214A, the second channel 214B and the third channel 214C are arranged one after the other such that the first channels 214A, the second channels 214B and the third channels 214C are evenly arranged on the base plate 210.

FIG. 2C shows a perspective view of the center sleeve cover 220 and the base plate 210 of FIG. 2A in combination. Specifically, the center sleeve cover 220 is disposed in the central zone 212, and the wall of the center sleeve cover 220 may have a plurality of slots 224 operatively coupled with inner ends of the separating plates 216 of the base plate 210, thereby resulting in the first cavity 260A. The first communicating openings 222 on the wall of the center sleeve cover 220 correspondingly connect to the first channels 214A, such that the first gas provided by the first pipe 237A can be transferred to the first cavity 260A, and then be evenly transferred to the first channels 214A of the base plate 210 via the first communicating openings 222.

FIG. 2D shows a perspective view of the inner cover 240, the outer cover 250 and the base plate 210 of FIG. 2A in combination. The inner cover 240 is disposed above the channels 214, and is disposed between the center sleeve cover 220 and the inner wall 234. The inner cover 240 may have a plurality of second communicating openings 242 correspondingly connected to the second channels 214B, such that the second gas provided by the second pipe 237B can be transferred to the second cavity 260B, and then be evenly transferred to the second channels 214B via the second communicating openings 242. To be more elaborate, the inner cover 240 may include a plurality of inner sub-cover elements 244 and a plurality of inner sub-connect elements 246. Each inner sub-connect element 246 is connected between two neighboring inner sub-cover elements 244 to result in the second communicating opening 242 between the inner sub-cover element 244 and the inner sub-connect element 246.

Likewise, the outer cover 250 is disposed above the channels 214, and is disposed between the inner wall 234 and the outer wall 236 to result in the third cavity 260C. The outer cover 250 may have a plurality of third communicating openings 252 correspondingly connected to the third channels 214C, such that the third gas provided by the third pipe 237C can be transferred to the third cavity 260C, and then be evenly transferred to the third channels 214C via the third communicating openings 252. To be more elaborate, the outer cover 250 may include a plurality of outer sub-cover elements 254 and a plurality of outer sub-connect elements 256. Each outer sub-connect element 256 is connected between two neighboring outer sub-cover elements 254 to result in the third communicating opening 252 between the outer sub-cover element 254 and the outer sub-connect element 256.

Referring back to FIG. 2A and FIG. 2B, the gas injector 200 may further include a channel cover plate 290. The channel cover plate 290 is disposed above the channels 214, and joins the outer wall 236 of the intake body 230. Due to the separating plates 216 and the channel cover plate 290, the first gas in the first channels 214A, the second gas in the second channels 214B and the third gas in the third channels 214C may be effectively separated.

In one embodiment, the channel cover plate 290 may include a cover body 291 and a plurality of control tabs 292. The cover body 291 joins the intake body 230. The control tabs 292 are connected to a periphery of the cover body 291, and each control tab 292 correspondingly covers an associated channel 214. The control tabs 292 may include first control tabs 292A, second control tabs 292B and third control tabs 292C, correspondingly covering the first channels 214A, the second channels 214B and the third channels 214C, respectively. To be more elaborate, a gap exists between neighboring control tabs 292 such that the control tabs 292 can be individually bent. In a preferred embodiment, each control tab 292 has a thickness less than 0.5 centimeter.

FIG. 2E shows a partial cross-sectional view of a gas injector 200 adaptable to semiconductor equipment according to another embodiment of the present invention. The gas injector 200 of the embodiment may include a regulating unit 270, which is fixed to the intake body 230 and operatively coupled to the channel cover plate 290 via a fixed plate 280, and is configured for regulating cross-sectional areas of the channels 214.

Specifically, the regulating unit 270 may include a plurality of first regulators 272A, second regulators 272B and third regulators 272C. The first regulator 272A is disposed above the first control tab 292A for adjusting deflection thereof. The second regulator 272B is disposed above the second control tab 292B for adjusting deflection thereof. The third regulator 272C is disposed above the third control tab 292C for adjusting deflection thereof. In a preferred embodiment, the first regulator 272A, the second regulator 272B and the third regulator 272C may include linear motion devices, which are capable of precisely controlling deflections of the first control tabs 292A, the second control tabs 292B and the third control tabs 292C, respectively. Accordingly, the cross-sectional areas of the first channels 214A, the second channels 214B and the third channels 241C can be adjusted according to requirements in order to effectively and precisely change flow velocities of the first gas, the second gas and the third gas.

Although specific embodiments have been illustrated and described, it will be appreciated by those skilled in the art that various modifications may be made without departing from the scope of the present invention, which is intended to be limited solely by the appended claims.

What is claimed is:

1. A gas injector, comprising:
a base plate including a central zone and a plurality of channels, the channels surrounding the central zone and being disposed on the base plate in sequence, the channels including first channels, second channels and third channels;
a center sleeve cover disposed in the central zone and operatively coupled with the base plate to form a first cavity, a wall of the center sleeve cover joining the channels and having a plurality of first communicating openings correspondingly connected to the first channels;
an intake body including a top portion, an inner wall and an outer wall, top surfaces of the inner wall and the outer wall being connected to the top portion, and bottom surfaces of the inner wall and the outer wall being disposed on the channels;
an inner cover disposed above the channels and disposed between the center sleeve cover and the inner wall to result in a second cavity, the inner cover having a plurality of second communicating openings correspondingly connected to the second channels; and
an outer cover disposed above the channels and disposed between the inner wall and the outer wall to result in a third cavity, the outer cover having a plurality of third communicating openings correspondingly connected to the third channels.

2. The gas injector of claim 1, wherein the base plate comprises a plurality of separating plates configured for separating the channels.

3. The gas injector of claim 1, wherein the plurality of channels comprise N first channels, N second channels and N third channels, where N is a positive integer.

4. The gas injector of claim 3, wherein the first channel, the second channel and the third channel are arranged one after the other such that the first channels, the second channels and the third channels are evenly arranged on the base plate.

5. The gas injector of claim 1, wherein the intake body further comprises:
a first pipe passing through the top portion of the intake body and connecting to the center sleeve cover for providing first gas to the first cavity;
a second pipe disposed on the top portion of the intake body and connected to the second cavity for providing second gas to the second cavity; and
a third pipe disposed on the top portion of the intake body and connected to the third cavity for providing third gas to the third cavity.

6. The gas injector of claim 2, wherein a wall of the center sleeve cover have a plurality of slots operatively coupled with inner ends of the separating plates of the base plate.

7. The gas injector of claim 1, wherein the inner cover comprises:
a plurality of inner sub-cover elements; and
a plurality of inner sub-connect elements;
wherein each said inner sub-connect element is connected between two neighboring inner sub-cover elements to result in the second communicating opening between the inner sub-cover element and the inner sub-connect element.

8. The gas injector of claim 1, wherein the outer cover comprises:
a plurality of outer sub-cover elements; and
a plurality of outer sub-connect elements;
wherein each said outer sub-connect element is connected between two neighboring outer sub-cover elements to result in the third communicating opening between the outer sub-cover element and the outer sub-connect element.

9. The gas injector of claim 1, further comprising a channel cover plate disposed above the channels and joining the intake body.

10. The gas injector of claim 9, wherein the channel cover plate comprises:
a cover body joining the intake body; and
a plurality of control tabs connected to a periphery of the cover body, each said control tab correspondingly covering an associated channel, the control tabs including first control tabs, second control tabs and third control tabs correspondingly covering the first channels, the second channels and the third channels respectively.

11. The gas injector of claim 10, wherein the control tab has a thickness less than 0.5 centimeter.

12. The gas injector of claim 10, further comprising a regulating unit configured for regulating cross-sectional areas of the channels, the regulating unit comprising:
a plurality of first regulators disposed above the first control tabs for adjusting deflection thereof;
a plurality of second regulators disposed above the second control tabs for adjusting deflection thereof; and
a plurality of third regulators disposed above the third control tabs for adjusting deflection thereof.

13. The gas injector of claim 12, wherein the first regulator, the second regulator and the third regulator comprise linear motion devices.
